(19) United States
(12) Patent Application Publication
(10) Pub. No.: US 2016/0009548 A1
(43) Pub. Date: Jan. 14, 2016

(54) MICROELECTROMECHANICAL SYSTEMS HAVING CONTAMINANT CONTROL FEATURES

(71) Applicant: SKYWORKS SOLUTIONS, INC., Woburn, MA (US)

(72) Inventors: Jerod F. MASON, Bedford, MA (US); Dylan Charles BARTLE, Arlington, MA (US); David Scott WHITEFIELD, Andover, MA (US); Dogan GUNES, North Andover, MA (US); Paul T. DICARLO, Marlborough, MA (US); David T. PETZOLD, Chelmsford, MA (US)

(21) Appl. No.: 14/688,128

(22) Filed: Apr. 16, 2015

Related U.S. Application Data
(60) Provisional application No. 61/981,169, filed on Apr. 17, 2014.

(51) Int. Cl. B81B 7/00; B81C 1/00

(52) U.S. Cl. CPC B81B 7/0041; B81C 1/00293; B81B 2201/014; B81B 2201/0235; B81B 2201/0242; B81B 2207/11; B81B 2201/0292

(57) ABSTRACT

Microelectromechanical systems (MEMS) having contaminant control features. In some embodiments, a MEMS die can include a substrate and an electromechanical assembly implemented on the substrate. The MEMS die can further include a contaminant control component implemented relative to the electromechanical assembly. The contaminant control component can be configured to move contaminants relative to the electromechanical assembly. For example, such contaminants can be moved away from the electromechanical assembly.

### CROSS-REFERENCE TO RELATED APPLICATION(S)

This application claims priority to U.S. Provisional Application No. 61/981,169 filed Apr. 17, 2014, entitled MICROELECTROMECHANICAL SYSTEMS HAVING CONTAMINANT CONTROL FEATURES, the disclosure of which is hereby expressly incorporated by reference herein in its entirety.

### BACKGROUND

1. Field

The present disclosure relates to microelectromechanical systems (MEMS) devices having contaminant control features.

2. Description of the Related Art

Microelectromechanical systems devices, or MEMS devices, typically include miniaturized mechanical and electro-mechanical elements. Such MEMS devices can include moving elements controlled by a controller to provide desired functionalities. MEMS devices are sometimes referred to as microsystems technology devices or micromachined devices.

### SUMMARY

In some teachings, the present disclosure relates to a microelectromechanical systems (MEMS) die that includes a substrate and an electromechanical assembly implemented on the substrate. The MEMS die further includes a contaminant control component implemented relative to the electromechanical assembly. The contaminant control component is configured to move contaminants relative to the electromechanical assembly.

In some embodiments, the contaminant control component can be configured to move the contaminants away from one or more portions of the electromechanical assembly. The MEMS die can be, for example, a switching device, a capacitance device, a gyroscope sensor device, an accelerometer device, a surface acoustic wave (SAW) device, or a bulk acoustic wave (BAW) device. In the example context of MEMS die being a switching device, such a switching device can be, for example, a contact switching device.

In some embodiments, the contaminant control component can include a contaminant capture component. The contaminant capture component can include a voltage element implemented on one or more sides of a perimeter of the MEMS die, and the voltage element can be configured to yield an electrostatic force when provided with high voltage. The voltage element can include a conductive ring implemented partially or fully along the perimeter. The conductive ring can include a conductive segment on a selected side of the perimeter. The conductive ring can include a substantially closed ring along the perimeter. The conductive ring can be implemented on a surface of the substrate.

In some embodiments, The MEMS die can further include a ground ring implemented along the perimeter of the die. The conductive ring can be configured relative to the ground ring to attract and burn off at least some of the contaminants.

In some embodiments, the contaminant capture component can include a voltage element implemented along one or more sides of the electromechanical assembly. The voltage element can be configured to yield an electrostatic force when provided with high voltage. The voltage element can include a conductive ring implemented partially or fully about the electromechanical assembly. The conductive ring can be configured to provide more of the electrostatic force to a selected portion of the electromechanical assembly. The selected portion can include a contact mechanism of the switching device. The conductive ring can include a substantially closed ring around the electromechanical assembly. The conductive ring can be implemented on a surface of the substrate.

In some embodiments, the contaminant capture component can include a first electrode implemented over the substrate to define a volume. The electrode can be configured to yield an electrostatic force within the volume when provided with high voltage to thereby capture at least some of the contaminants from the volume. The first electrode can be offset above the surface of the substrate by a plurality of posts that are mounted on the substrate. The contaminant capture component can further include a second electrode implemented generally underneath the first electrode. The first and second electrodes can be configured to be capable of being provided with a potential difference to attract contaminants to one of the electrodes.

In accordance with a number of implementations, the present disclosure relates to a method for fabricating a microelectromechanical systems (MEMS) apparatus. The method includes providing a substrate, and forming an electromechanical assembly on the substrate. The method further includes forming a contaminant control component relative to the electromechanical assembly, where the contaminant control component is configured to move contaminants relative to the electromechanical assembly.

In some implementations, the present disclosure relates to a radio-frequency (RF) module that includes a substrate configured to receive a plurality of components, and an RF MEMS apparatus implemented on the substrate. The RF MEMS apparatus includes an electromechanical assembly, and a contaminant control component implemented relative to the electromechanical assembly. The contaminant control component is configured to move contaminants relative to the electromechanical assembly.

In some embodiments, the contaminant control component can be configured to move the contaminants away from one or more portions of the electromechanical assembly. In some embodiments, the RF MEMS apparatus can be a MEMS die. In some embodiments, the RF MEMS apparatus can include an RF switch. In some embodiments, the RF module can be an antenna switch module (ASM).

In some embodiments, the RF MEMS apparatus can be sealed on or within the substrate. In some embodiments, the RF MEMS apparatus can be hermetically sealed on or within the substrate. In some embodiments, the RF MEMS apparatus can be non-hermetically sealed on or within the substrate. In some embodiments, the RF MEMS apparatus may or may be not sealed on or within the substrate.

According to some teachings, the present disclosure relates to a method for fabricating a radio-frequency (RF) module. The method includes providing a substrate configured to receive a plurality of components, and mounting or forming an RF MEMS die on the substrate. The RF MEMS die includes an electromechanical assembly, and a contaminant control component implemented relative to the electromechanical assembly. The contaminant control component is configured to move contaminants relative to the electromechanical assembly.

In some implementations, the present disclosure relates to a radio-frequency (RF) device that includes a receiver configured to process RF signals, and a front-end module (FEM) in communication with the receiver. The FEM includes switching circuit. The switching circuit includes an RF MEMS die having an electromechanical assembly and a contaminant control component implemented relative to the electromechanical assembly. The contaminant control component is configured to move contaminants relative to the electromechanical assembly. The RF device further includes an antenna in communication with the FEM.

In some embodiments, the RF device can be a wireless device. Such a wireless device can be, for example, a cellular phone.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

Figure shows a block diagram of a microelectromechanical systems (MEMS) device implemented as a die and having a contaminant control component.

FIG. 2 shows that in some embodiments, the contaminant control component of FIG. 1 can be configured to capture loose contaminant particles to thereby move them away from one or more selected regions.

FIGS. 3A-3C show non-limiting examples of different levels of contaminant capture functionalities that can be implemented on a MEMS die.

FIGS. 4A-4C show side views of a MEMS contact switch that utilizes high voltage to actuate mechanical movements for its operation.

FIG. 5 shows a MEMS apparatus that does not include a contaminant capture feature.

FIG. 6 shows an example MEMS apparatus having a plurality of MEMS devices implemented on a substrate, and a voltage ring implemented generally around the perimeter of the substrate.

FIG. 7 shows an example configuration where a MEMS die can include one or more MEMS device-specific features configured to provide contaminant capture functionality.

FIG. 8 shows an example where local voltage rings are not necessarily complete rings.

FIG. 9 shows an example where a perimeter voltage trace does not form a complete perimeter.

FIG. 10 shows an example configuration where a two-dimensional voltage pad can be implemented relative to each of a plurality of MEMS devices on a die.

FIG. 11 shows an example configuration that includes a voltage electrode implemented above a volume where contamination capture coverage is desired.

FIG. 12 shows an example configuration that includes a pair of electrodes implemented about a volume where contamination capture coverage is desired.

FIG. 13 shows that in some embodiments, one or more MEMS devices as described herein can be implemented in a module.

FIG. 14 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

Disclosed are various examples related to microelectromechanical systems (MEMS) and how such systems can include a component configured to provide control of contaminants. Although various examples are described in the context of MEMS, it will be understood that one or more features of the present disclosure can also be utilized in other electromechanical systems having dimensions larger or smaller (e.g., NEMS) than typical MEMS dimensions.

FIG. 1 shows a block diagram of a MEMS device implemented as, for example, a die 100 and having a contaminant control component 102. In some embodiments, such a component can be implemented substantially within the MEMS device boundary and/or volume, and be configured to move loose contaminant particles away from, or towards, one or more selected regions.

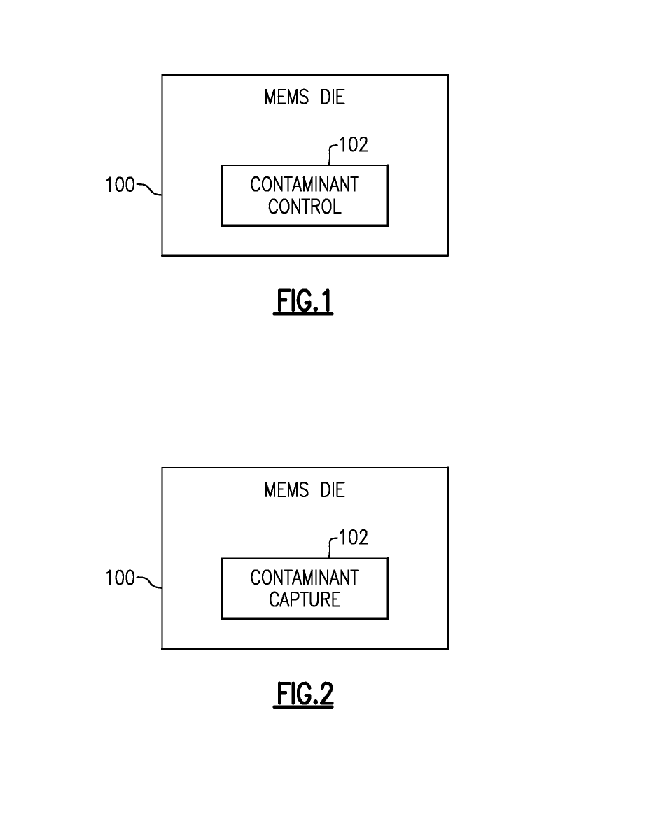

FIG. 2 shows that in some embodiments, the contaminant control component 102 of FIG. 1 can be configured to capture loose contaminant particles to thereby move them away from one or more selected regions. Various examples are described herein in the context of such capture functionalities; however, it will be understood that similar control of contaminants can be achieved by, for example, repelling contaminant particles from one or more selected regions.

As is generally understood, a MEMS die typically includes an electromechanical assembly implemented on a substrate. Such an electromechanical assembly can be configured to yield mechanical changes based on electrical inputs; and such mechanical changes can yield changes in electrical properties of the electromechanical assembly. Contact switches and capacitors are examples of devices that can be implemented in MEMS form factors. Although various examples are described herein in the contexts of such switches and capacitors, it will be understood that one or more features of the present disclosure can also be utilized in other MEMS devices.

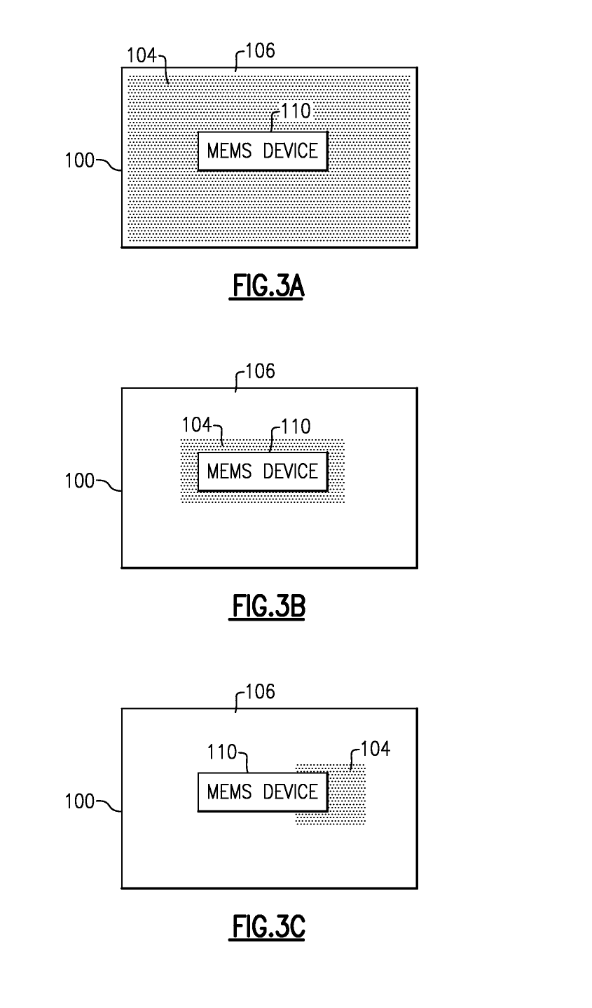

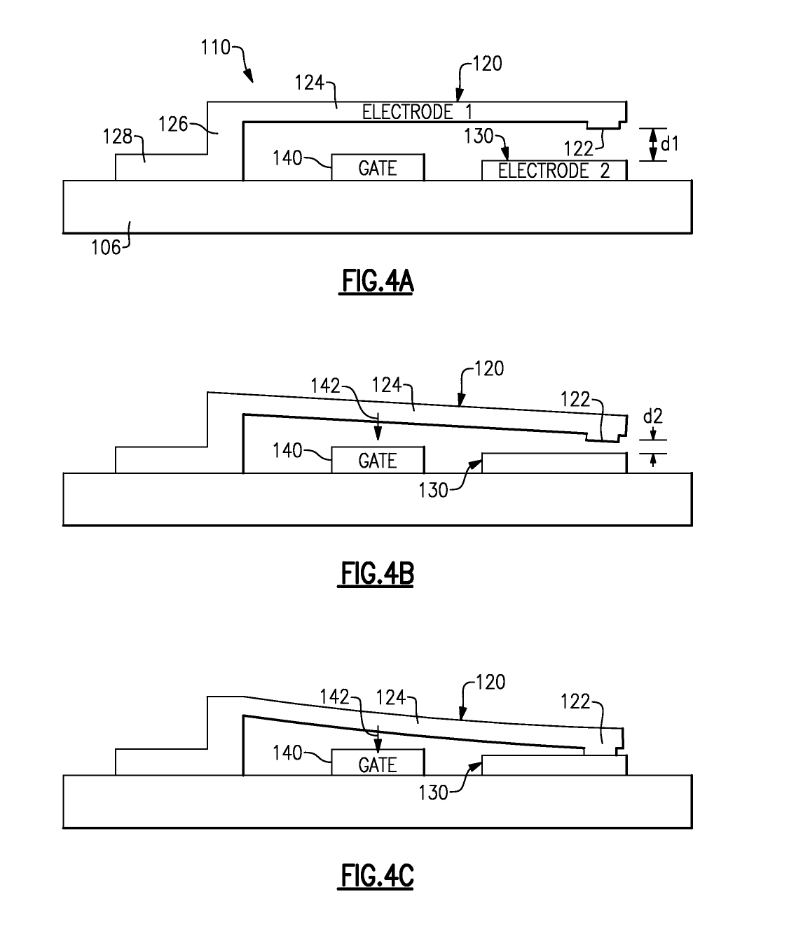

FIGS. 3A-3C show non-limiting examples of different levels of contaminant capture functionalities that can be implemented on a MEMS die 100. For the purpose of description of FIGS. 3A-3C, one MEMS device 110 is shown to be implemented on a substrate 106 of the die 100; however, it will be understood that a plurality of MEMS devices can be implemented on a given die.

For the purpose of description herein, it will be understood that a MEMS device may refer to an electromechanical assembly, a MEMS die having such an assembly, or any other combination that includes an electromechanical assembly as described in appropriate context. It will also be understood that references to areas or regions of contamination control coverage as described herein can extend to volumes in appropriate context.

In the example of FIG. 3A, a contaminant capture component can be configured to provide a substantially die-wide coverage 104 in which contaminant particles can be captured. Effectiveness of capturing such particles in the coverage region 104 may or may not be uniform; however, such a coverage region can move contaminant particles generally away from the MEMS device 110.

In the example of FIG. 3B, a contaminant capture component can be configured to provide a more localized coverage 104 in which contaminant particles can be captured. Such a localized coverage region can cover, for example, substantially all of the MEMS device 110. Due to the localized nature, the example coverage 104 of FIG. 3B can be more efficient than the example of FIG. 3A.

In the example of FIG. 3C, a contaminant capture component can be configured to provide even more localized coverage 104 in which contaminant particles can be captured. Such a localized coverage region can cover, for example, a selected region relative to the MEMS device 110. Such a selected region can be at or near one or more portions of the MEMS device that is/are susceptible to damage and/or performance degradation from contaminant particles. Again, due to the localized nature, the example coverage 104 of FIG. 3C can be relatively efficient.

Controlling of contaminants (e.g., by capturing them) in MEMS as described herein can be beneficial for a number of reasons. For example, MEMS device performance can be highly sensitive to contamination issues. Such contamination can result from use of high voltages to actuate electromechanical assemblies. For example, many types of contaminants, including those of organic nature, are typically attracted to high voltages. Over time, these types of contaminants can migrate toward the high voltage sources and eventually degrade the performance of the MEMS devices.

By way of an example, FIGS. 4A-4C show side views of a MEMS contact switch 110 that utilizes high voltage to actuate mechanical movements for its operation. Contaminants can impact part(s) associated with such high voltage. Contaminants can also be generated by repeated movements associated with such mechanical actuations.

In the example of FIGS. 4A-4C, the MEMS contact switch 110 is shown to include a first electrode 120 implemented as a beam 124. The beam 124 is supported on a post 126 which is in turn mounted on a substrate 106 through a base 128. The first electrode 120 is shown to include a contact pad 122 formed at or near the end opposite from the post 126. When the switch 110 is in an OFF state (FIG. 4A), the beam 124 can be in its relaxed state such that the contact pad 122 is separated from a second electrode 130 by a distance d1. When the switch 110 is in an ON state (FIG. 4C), the beam 124 can be in its flexed state such that the contact pad 122 is touching the second electrode 130 so as to form an electrical connection between the first electrode 120 and the second electrode 130.

In the example MEMS contact switch 110, transition between the foregoing OFF and ON states can be effectuated by a gate 140 configured to provide electrostatic actuation. Thus, when an actuation signal such as high voltage is applied to the gate 140, the gate 140 can apply an attractive electrostatic force (arrow 142) on the beam 124 to thereby pull on the beam 124. Accordingly, the contact pad 122 of the first electrode 120 moves closer to the second electrode 130 (e.g., in an intermediate stage in FIG. 4B with a gap distance of d2), until the two physically touch to close the circuit between the first and second electrodes 120, 130. When the actuation signal is removed from the gate 140, the attractive force 142 is removed. Accordingly, the beam 124 can return to its relaxed state of FIG. 4A.

As one can see from the foregoing example, the electrostatic force provided by the gate 140 to attract the beam 124 can also attract various contaminant particles.

FIG. 5 shows a MEMS apparatus 10 that does not include a contaminant capture feature. The example apparatus 10 is shown to include a plurality of MEMS devices 110 implemented on a substrate 106. The example apparatus 10 can also include one or more ground rings (e.g., 150, 152). Such ground rings can be configured to provide, for example, mechanical integrity, robustness to moisture ingression, a reference potential and/or ground to the substrate, a convenient path to ground in a layout, and/or a path for electrostatic discharge (ESD).

In the example of FIG. 5, there is no feature outside of the MEMS devices 110 that can attract contaminants. Accordingly, such contaminants are likely attracted to the MEMS devices 110 due to their operations, and can generally remain there.

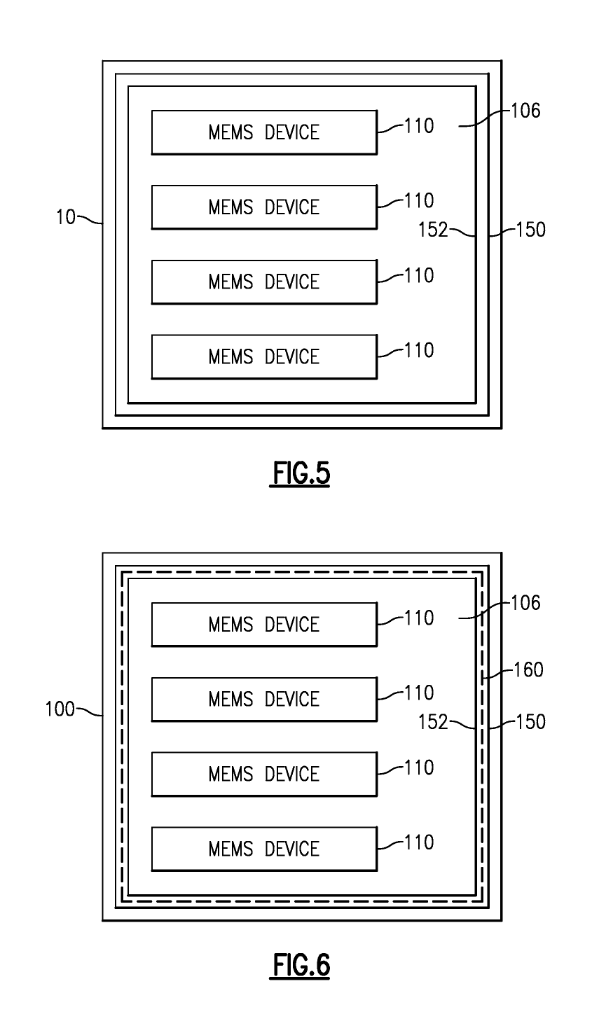

FIGS. 6-12 show various non-limiting examples of contaminant capture configurations that can be implemented to yield one or more contaminant capture functionalities of FIGS. 3A-3C. For example, FIG. 6 shows a MEMS apparatus 100 (e.g., a MEMS die) having a plurality of MEMS devices 110 implemented on a substrate 106. Similar to the example of FIG. 5, the MEMS die 100 of FIG. 6 is shown to include two ground rings, an outer ground ring 150 and an inner ground ring 152.

In the example of FIG. 6, however, a voltage ring 160 is shown to be implemented generally around the perimeter of the substrate 106. Although depicted between the two ground rings 150, 152, such a voltage ring can be implemented inward of the inner ground ring 152 or outward of the outer ground ring 150. Further, the voltage ring 160 may or may not form a continuous perimeter around the substrate 106. For example, the voltage ring 160 can include a plurality of segments that are electrically connected to one or more voltages (which may or may not be the same). Further, the voltage ring 160 may or may not be on the surface of the substrate 106. For example, one or more portions of the voltage ring 160 can be partially or fully embedded in the substrate 106. In another example, one or more portions of the voltage ring 160 can be implemented above the surface of the substrate 106. Other variations can also be implemented.

The voltage ring 160 in the example of FIG. 6 can be operated to attract contaminant particles generally towards the perimeter of the die 100, and thereby away from the MEMS devices 110. Depending on factors such as die dimensions and voltage applied to the voltage ring 160, contaminant capture coverage for the entire area of the die 100 may or may not be uniformly effective. For example, portions of the middle MEMS devices that are near the center of the die 100 are relatively far from the voltage ring 160; accordingly, contaminants in those areas may not feel sufficiently strong attractive force from the voltage ring 160.

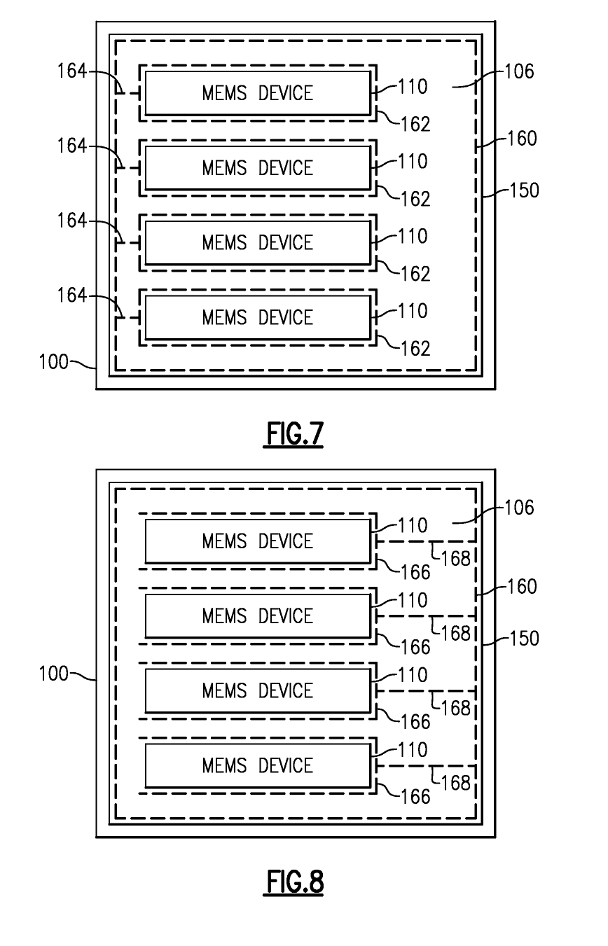

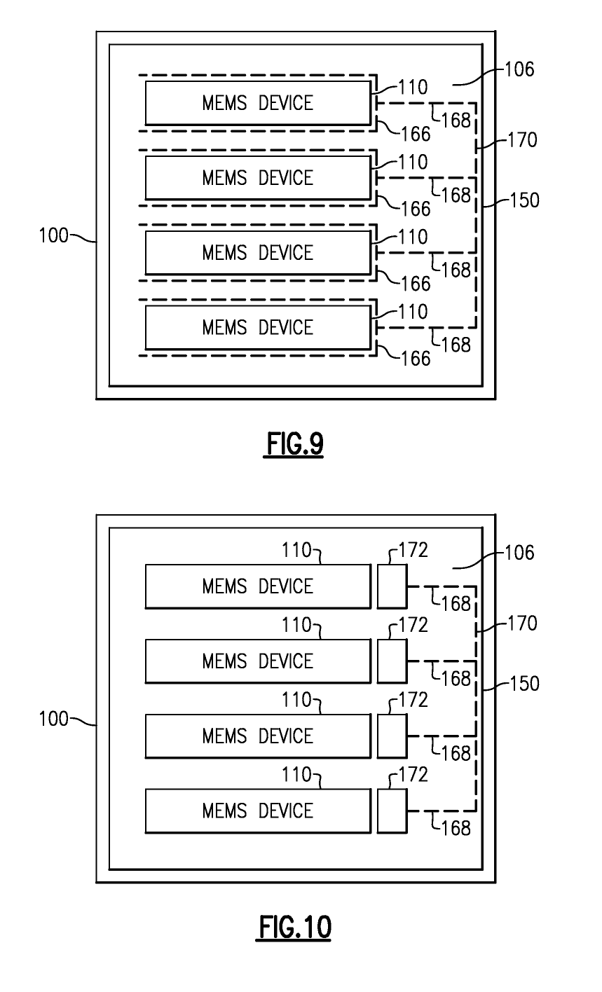

FIG. 7 shows an example configuration where a MEMS die 100 can include one or more MEMS device-specific features configured to provide contaminant capture functionality. In the example of FIG. 7, a voltage ring 160 is shown to be implemented inward of a ground ring 150. It will be understood that such a ring can also be implemented outward of the ground ring 150. Further, the voltage ring 160 may or may not be present in the example of FIG. 7.

In the example of FIG. 7, each of the four example MEMS devices 110 is shown to be surrounded by a local voltage ring 162. Such local voltage rings are shown to be electrically connected to the perimeter voltage ring 160 by conductors 164. Each local voltage ring 162 may or may not form a continuous perimeter around its respective MEMS device 110. For example, the local voltage ring 162 can include a plurality of segments that are electrically connected to one or more voltages (which may or may not be the same). Further, the local voltage ring 162 may or may not be on the surface of the substrate 106. For example, one or more portions of the local voltage ring 162 can be partially or fully embedded in the substrate 106. In another example, one or more portions of the local voltage ring 162 can be implemented above the surface of the substrate 106. Other variations can also be implemented.

The local voltage rings 162 in the example of FIG. 7 can be operated to attract contaminant particles more locally relative to the MEMS devices 110. Such localized capture of contaminants can provide more effective coverage for the MEMS devices 110. Depending on factors such as die dimensions and voltage(s) applied to the perimeter voltage ring 160 and the local voltage rings 162, not all of the MEMS devices 110 may need local voltage rings 162. For example, MEMS devices that are sufficiently close to the perimeter voltage ring 160 may not need local voltage rings.

In the example of FIG. 7, the local voltage rings 162 are depicted as being electrically connected to the perimeter voltage ring 160. It will be understood that such connections are not necessarily required. In some embodiments, some or all of the local voltage rings 162 can be isolated from the perimeter voltage ring 160 and be operated independently. In some embodiments, some of the local voltage rings 162 can be coupled and operated with the perimeter voltage ring 160, and the remaining local voltage ring(s) 162 can be isolated and operated separately from the perimeter voltage ring 160.

FIG. 8 shows an example where local voltage rings are not necessarily complete rings. Each of the four example MEMS devices 110 is shown to be partially surrounded by a local voltage ring 166. More particularly, three of the four sides of the MEMS device 110 are provided with respective voltage segments of the voltage ring 166, and the remaining side (e.g., on the left side in FIG. 8) does not have a corresponding voltage segment. In each of the example local voltage rings 166, the three segments may or may not form a continuous U-shape. For example, the U-shaped local voltage ring 166 can include a plurality of segments that are electrically connected to one or more voltages (which may or may not be the same). Further, the U-shaped local voltage ring 166 may or may not be on the surface of the substrate 106. For example, one or more portions of the U-shaped local voltage ring 166 can be partially or fully embedded in the substrate 106. In another example, one or more portions of the U-shaped local voltage ring 166 can be implemented above the surface of the substrate 106. Other variations can also be implemented.

As described herein, a ring can be a voltage structure that completely or partially surrounds an object or a region (e.g., a MEMS device or an inner region on a die). In some situations, such a voltage structure may also be referred to herein as a voltage trace, a trace, voltage segment or a segment. Further, although various examples are described in the context of such voltage traces or segments being one or more straight sections, it will be understood that a trace or a segment can include a curved shape.

In the example of FIG. 8, the U-shaped local voltage traces 166 are shown to be electrically connected to a perimeter ring 160 through their respective conductors 168. It is noted that the conductors 168 themselves can provide contaminant capture functionality. More particularly, the base of the U shape which is opposite from the uncovered side of the MEMS device 110 is shown to be connected to the conductor 168. Such a configuration can be implemented when the uncovered side (e.g., left side in FIG. 8) of the MEMS device 110 is not sensitive to contaminants, not likely to generate contaminants, or any combination thereof. The side (e.g., right side in FIG. 8) covered by the base of the U shape and/or the conductor 168 can be for a portion of the MEMS 110 that is sensitive to contaminants, likely to generate contaminants, or any combination thereof.

In the example of FIG. 8, the local voltage traces 166 are depicted as being electrically connected to the perimeter voltage ring 160. It will be understood that such connections are not necessarily required. In some embodiments, some or all of the local voltage traces 166 can be isolated from the perimeter voltage ring 160 and be operated independently. In some embodiments, some of the local voltage traces 166 can be coupled and operated with the perimeter voltage ring 160, and the remaining local voltage trace(s) 166 can be isolated and operated separately from the perimeter voltage ring 160.

In the foregoing examples of FIGS. 6-8, the perimeter voltage rings 160 are depicted as forming substantially complete rings at or near the perimeters of the die 100. FIG. 9 shows an example where a perimeter voltage trace 170 does not form a complete perimeter. Instead, the perimeter voltage trace 170 is shown to be a segment that covers some or all of a selected side (e.g., right side in FIG. 9) of the die 100. Although shown with coverage of only one side, more than one side of the die 100 can be covered by the perimeter voltage trace 170.

In the example of FIG. 9, the perimeter voltage segment 170 is shown to be electrically connected to local voltage traces 166 through conductors 168 in manners similar to the example of FIG. 8. Similar to the example of FIG. 8, the selected side (e.g., right side in FIG. 9) with the perimeter voltage segment 170, the conductors 168, and the covered side of the local voltage traces 166 can be implemented to provide effective contaminant capture coverage for portions of the MEMS devices that are sensitive to contaminants, likely to generate contaminants, or any combination thereof.

In the example of FIG. 9, the local voltage traces 166 are depicted as being electrically connected to the perimeter voltage segment 170. It will be understood that such connections are not necessarily required. In some embodiments, some or all of the local voltage traces 166 can be isolated from the perimeter voltage segment 170 and be operated independently. In some embodiments, some of the local voltage traces 166 can be coupled and operated with the perimeter voltage segment 170, and the remaining local voltage trace(s) 166 can be isolated and operated separately from the perimeter voltage segment 170.

In the examples of FIGS. 6-9, various voltage features (e.g., perimeter voltage rings/traces 160, 170, local voltage rings/traces 162, 166, conductors 164, 168) are described as being segments or lines. FIG. 10 shows that a voltage feature having one or more functionalities as described herein can be implemented as a two- or three-dimensional feature.

For example, FIG. 10 shows a configuration where a two-dimensional voltage pad 172 can be implemented relative to each of a plurality of MEMS devices 110 on a die 100. Such positioning of the voltage pads 172 can be selected to provide contamination capture coverage for portions of the MEMS devices 110 that are sensitive to contaminants, likely to generate contaminants, or any combination thereof. In the example of FIG. 10, the right side of the MEMS devices 110 can be provided with such coverage.

In the example of FIG. 10, the voltage pads 172 can be formed on the surface of the substrate 106. However, such surface implementation of the voltage pads 172 is not necessarily a requirement. For example, one or more portions of each voltage pad 172 can be partially or fully embedded in the substrate 106. In another example, one or more portions of the voltage pad 172 can be implemented above the surface of the substrate 106. Other variations can also be implemented. Further, although the voltage pad 172 is depicted as a rectangle, it will be understood that other shapes can also be implemented. Further, although the voltage pads 172 are depicted as a contiguous pads, it will be understood that a given voltage pad can be implemented with two or more sub-pads.

In the example of FIG. 10, the voltage pads 172 are depicted as being electrically connected to a perimeter voltage segment 170 through conductors 168. It will be understood that such connections are not necessarily required. In some embodiments, some or all of the voltage pads 172 can be isolated from the perimeter voltage segment 170 and be operated independently. In some embodiments, some of the voltage pads 172 can be coupled and operated with the perimeter voltage segment 170, and the remaining voltage pad(s) 172 can be isolated and operated separately from the perimeter voltage segment 170.

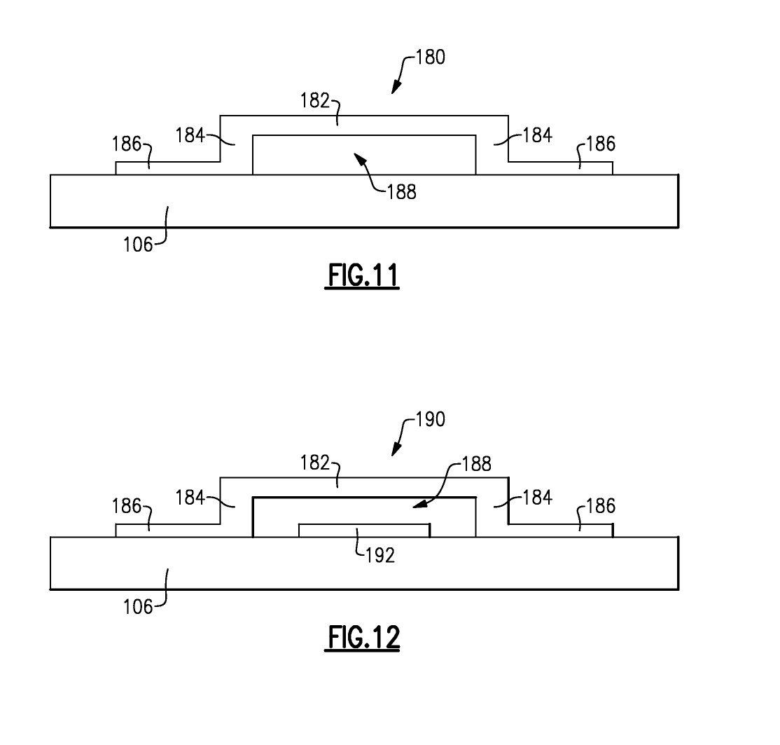

FIGS. 11 and 12 show examples three-dimensional structures that can be configured to provide contamination capture functionality. For example, FIG. 11 shows a configuration 180 that includes a voltage electrode 182 implemented above a volume 188 where contamination capture coverage is desired. The example voltage electrode 182 can be positioned at a desired height above the substrate 106 by, for example, appropriately dimensioned posts 184. Such posts can be mounted to the substrate 106 through their respective bases 186.

In the example of FIG. 11, the voltage electrode 182 can be dimensioned and positioned on a MEMS die to provide desired contaminant capture functionality, as well as to optimize or improve the layout and overall device performance. In some embodiments, ground ring(s) or plate(s) can be implemented relative to the voltage electrode 182 as needed or desired for a given system.

In another example, FIG. 12 shows a configuration 190 that includes a pair of electrodes 182, 192 implemented about a volume 188 where contamination capture coverage is desired. The first electrode 182 can be similar to the example voltage electrode 182 of FIG. 11. For example, the first electrode 182 can be positioned at a desired height above the substrate 106 by, for example, appropriately dimensioned posts 184. Such posts can be mounted to the substrate 106 through their respective bases 186.

The second electrode 192 can be implemented as a plate on the surface of the substrate 106 in an area that is generally underneath the first electrode 182. In this example, a potential difference can be provided between the first electrode 182 and the second electrode 192; and such a potential difference can be utilized to attract and capture contaminant particles from, for example, the volume 188.

In the example of FIG. 12, the electrodes 182, 192 can be dimensioned and positioned on a MEMS die to provide desired contaminant capture functionality, as well as to optimize or improve the layout and overall device performance. In some embodiments, ground ring(s) or plate(s) can be implemented relative to the electrodes 182, 192 as needed or desired for a given system.

Based on the various examples described herein, one can see that one or more contaminant capture elements can be implemented in a MEMS die so as to provide improved control of contaminant particles. In the context of such elements being voltage elements to attract contaminant particles, an appropriate voltage can be provided to a given voltage element (e.g., a ring, trace, segment, pad, or three-dimensional electrode) in a number of ways. For example, voltage elements can be provided with high voltage signals independently from control high voltage signals that are provided to MEMS devices. In another example, voltage elements can be configured to provide dual functionality as a control line to provide control high voltages to the MEMS devices, as well as to provide contaminant capture functionality. A combination of the foregoing two examples, as well as other variations, can also be implemented.

In some of the examples disclosed herein, voltage elements are described as being implemented relative to one or more grounding features such as rings. In such configurations, contaminants attracted by the voltage elements can be neutralized by the combination of the voltage element and the grounding feature.

In other examples disclosed herein, voltage elements are described as being stand-alone elements. In such configurations, contaminants can be attracted and retained at or near the voltage elements.

In some embodiments, voltages provided to voltage elements as described herein can be based on control high voltages utilized for the MEMS devices. For example, high voltage signals provided to the gates can be utilized (with similar amplitude or adjusted amplitude) by the voltage elements to attract contaminant particles. In the context of gate control voltages, such voltages are typically provided intermittently. Accordingly, voltage elements can also exert attractive forces of contaminant particles intermittently. Even though such attractive force is not applied constantly, the contaminant particles that are already collected by the voltage elements will likely not move away unless acted on by other forces.

Accordingly, in some embodiments, operation of voltage elements as described herein can be configured to make it more likely for contaminant particles to move toward one or more voltage element than to move toward a location associated with a given MEMS device. For example, if removal of contaminant particles from the contact region of a MEMS contact switch is desired, one or more voltage elements can be implemented relative to the contact region so as to make movement of contaminant particles more likely toward such voltage elements rather than toward the gate.

In some of the examples disclosed herein (e.g., FIGS. 6-10), various voltage elements can be configured to be displaced generally laterally from the MEMS devices. In the context of contact switches where the beam moves vertically, such a lateral position of the voltage elements results in electrostatic forces that have little or no effect on the generally vertical beam-actuation force.

In some of the examples disclosed herein, voltage elements can be implemented as three-dimensional features, and thereby can involve vertical electrostatic forces to attract contaminant particles. In the context of contact switches where the beam moves vertically, such elements can be configured and/or positioned relative to the beam to have little or no impact on its mechanical operation.

In the various examples disclosed herein, the MEMS devices are described in the context of switching devices. It will be understood that other types of MEMS devices can also benefit from one or more features as described herein. For example, a MEMS capacitor can include a movable beam similar to that of a contact switch. Contaminants accumulated at one or more locations of such a MEMS capacitor can impact its mechanical operation, as well as undesirably impact electrical properties.

It will also be understood that, although various examples are described herein in the contexts of contact MEMS devices (such as contact switches) and capacitive MEMS devices, one or more features of the present disclosure can also be implemented in other MEMS applications and/or applications involving electromechanical devices. Such applications and/or devices can include, but are not limited to, gyroscopes, accelerometers, surface acoustic wave (SAW) devices, bulk acoustic wave (BAW) devices, and any other MEMS devices that are sensitive to contaminants. In the context of contact switches, other RF and/or non-RF applications can include, for example, load switches in power supplies, voltage converters and regulators (e.g., where MEMS switches can replace FET switches); and power switches such as those configured to handle high power and/or high voltage (e.g., low frequency) signals.

MEMS devices having one or more features as described herein can be utilized in a number of electronic applications, including radio-frequency (RF) applications. In the context of RF applications, electrostatically-actuated MEMS devices, such as the MEMS switches and MEMS capacitors as described herein, can provide desirable characteristics such as low insertion loss, high isolation, high linearity, high power handling capability, and/or high Q factor.

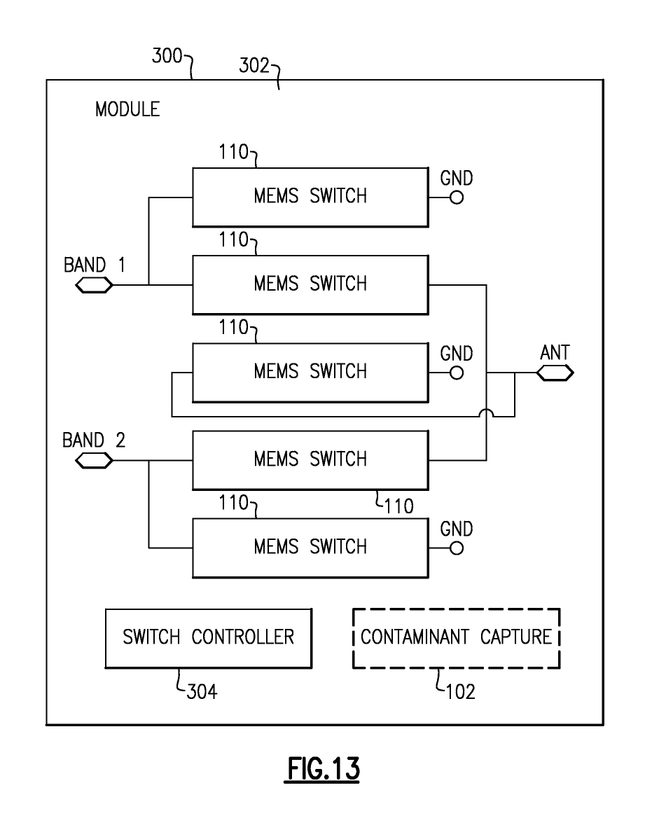

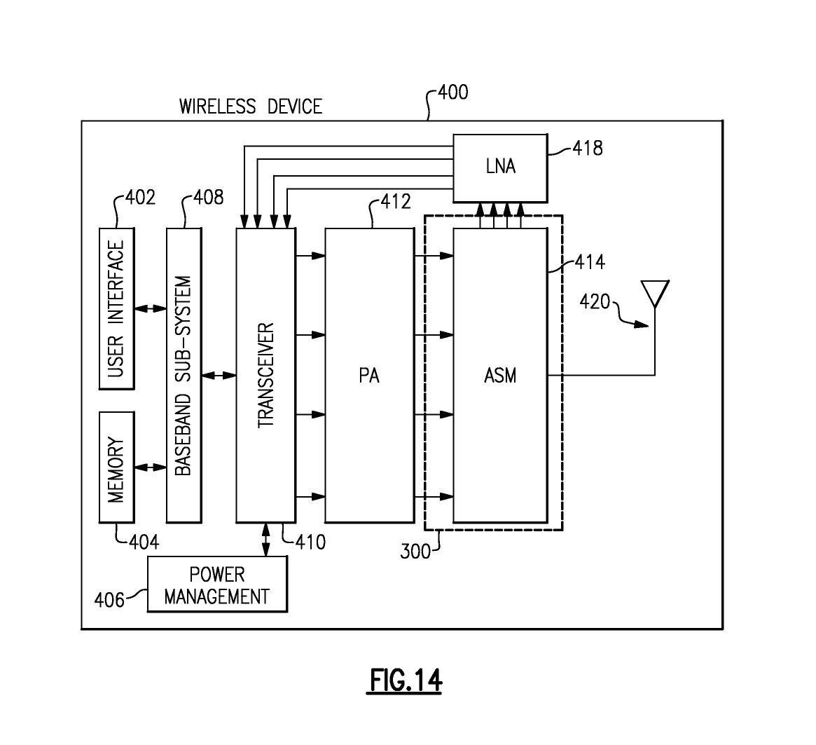

FIG. 13 shows that in some embodiments, one or more MEMS devices as described herein can be implemented in a module 300. The example module 300 can be implemented on a substrate 302. If the module 300 is in a die form, the substrate 302 can be a MEMS substrate (e.g., 106 in FIGS. 6-12). If the module 300 includes MEMS die mounted on another substrate, the substrate 302 can be, for example, a packaging substrate.

In the example module 300, a contaminant capture component 102 having one or more features as described herein can be implemented relative to one or more MEMS devices such as MEMS switches 110. Such a contaminant capture component can be implemented appropriately to accommodate a particular packaging configuration of the module 300.

In the example of FIG. 13, five of such MEMS devices 110 are shown to be connected between three example ports to provide RF switching functionalities. In the example of FIG. 13, a switch controller component 304 is also depicted as being implemented on the module 300. Other components can also be implemented on the module 300.

In some embodiments, the module 300 can be an antenna switching module (ASM) configured to provide switchable paths between a common antenna port (ANT) and two ports associated with, for example, two frequency bands (Band 1, Band 2). The path between the ANT port and the Band 1 port is shown to include a MEMS switch; similarly, the path between the ANT port and the Band 2 port is shown to include a MEMS switch. Each of the ANT port, Band 1 port, and Band 2 port is shown to be provided with a switchable shunt path to ground; and such switching functionality can be provided by a MEMS switch. In some embodiments, such MEMS switches for the shunt paths to ground can be configured as self-actuating switches.

In some embodiments, the module 300 can be a front-end module (FEM) in which case other components such as power amplifiers, low-noise amplifiers, matching circuits, and/or duplexers/filters can be included.

It will be understood that one or more features of the present disclosure can be implemented in MEMS devices that are hermetically sealed, non-hermetically sealed, or not sealed. For example, the MEMS devices 110 and the contaminant capture component 102 of FIG. 13 may be hermetically sealed, non-hermetically sealed, or not sealed on or within the module 300.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

FIG. 14 depicts an example wireless device 400 having one or more advantageous features described herein. In some embodiments, such advantageous features can be implemented in a module 300 such as an antenna switch module (ASM). In some embodiments, such module can include more or less components than as indicated by the dashed box.

Power amplifiers (PAs) in a PA module 412 can receive their respective RF signals from a transceiver 410 that can be configured and operated to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 is also shown to be connected to a power management component 406 that is configured to manage power for the operation of the wireless device 400. Such power management can also control operations of the baseband sub-system 408 and other components of the wireless device 400.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, the module 300 can include one or more MEMS devices, and be configured to provide one or more desirable functionalities as described herein. Such MEMS devices can facilitate, for example, operation of the antenna switch module (ASM) 414 while benefiting from improved conditions with respect to contaminants. In some embodiments, at least some of the signals received through an antenna 420 can be routed from the ASM 414 to one or more low-noise amplifiers (LNAs) 418. Amplified signals from the LNAs 418 are shown to be routed to the transceiver 410.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A microelectromechanical systems (MEMS) die comprising:
a substrate;
an electromechanical assembly implemented on the substrate; and
a contaminant control component implemented relative to the electromechanical assembly, the contaminant control component configured to move contaminants relative to the electromechanical assembly.

2. The MEMS die of claim 1 wherein the contaminant control component is configured to move the contaminants away from one or more portions of the electromechanical assembly.

3. The MEMS die of claim 2 wherein the MEMS die is a switching device, a capacitance device, a gyroscope sensor device, an accelerometer device, a surface acoustic wave (SAW) device, or a bulk acoustic wave (BAW) device.

4. The MEMS die of claim 2 wherein the contaminant control component includes a contaminant capture component.

5. The MEMS die of claim 4 wherein the contaminant capture component includes a voltage element implemented on one or more sides of a perimeter of the MEMS die, the voltage element configured to yield an electrostatic force when provided with high voltage.

6. The MEMS die of claim 5 wherein the voltage element includes a conductive ring implemented partially or fully along the perimeter.

7. The MEMS die of claim 6 wherein the conductive ring is implemented on a surface of the substrate.

8. The MEMS die of claim 6 further comprising a ground ring implemented along the perimeter of the die.

9. The MEMS die of claim 8 wherein the conductive ring is configured relative to the ground ring to attract and burn off at least some of the contaminants.

10. The MEMS die of claim 4 wherein the contaminant capture component includes a voltage element implemented along one or more sides of the electromechanical assembly, the voltage element configured to yield an electrostatic force when provided with high voltage.

11. The MEMS die of claim 10 wherein the voltage element is configured to provide more of the electrostatic force to a selected portion of the electromechanical assembly.

12. The MEMS die of claim 11 wherein the selected portion includes a contact mechanism of the switching device.

13. The MEMS die of claim 11 wherein the voltage element is implemented on a surface of the substrate.

14. The MEMS die of claim 4 wherein the contaminant capture component includes a first electrode implemented over the substrate to define a volume, the electrode configured to yield an electrostatic force within the volume when provided with high voltage to thereby capture at least some of the contaminants from the volume.

15. The MEMS die of claim 14 wherein the first electrode is offset above the surface of the substrate by a plurality of posts that are mounted on the substrate.

16. The MEMS die of claim 15 wherein the contaminant capture component further includes a second electrode implemented generally underneath the first electrode, the first and second electrodes configured to be capable of being provided with a potential difference to attract contaminants to one of the electrodes.

17. A method for fabricating a microelectromechanical systems (MEMS) apparatus, the method comprising:
providing a substrate;
forming an electromechanical assembly on the substrate; and
forming a contaminant control component relative to the electromechanical assembly, the contaminant control component configured to move contaminants relative to the electromechanical assembly.

18. A radio-frequency (RF) module comprising:
a substrate configured to receive a plurality of components; and
an RF MEMS apparatus implemented on the substrate, the RF MEMS apparatus including an electromechanical assembly, the RF MEMS apparatus further including a contaminant control component implemented relative to the electromechanical assembly, the contaminant control component configured to move contaminants relative to the electromechanical assembly.

19. The RF module of claim 18 wherein the RF MEMS apparatus includes an RF switch.

20. The RF module of claim 19 wherein the RF module is an antenna switch module (ASM).
